(19) United States
(12) Patent Application Publication
(10) Pub. No.: US 2025/0314722 A1
(43) Pub. Date: Oct. 9, 2025

(54) Object Localization in MR Tomography Examination Tubes

(71) Applicant: Siemens Healthineers AG, Forchheim (DE)

(72) Inventor: David Grodzki, Erlangen (DE)

(73) Assignee: Siemens Healthineers AG, Forchheim (DE)

(21) Appl. No.: 19/171,722

(22) Filed: Apr. 7, 2025

(30) Foreign Application Priority Data
Apr. 8, 2024 (EP) 24168911.6

(51) Int. Cl. G01R 33/28; G01R 33/30; G01R 33/381; G01R 33/48

(52) U.S. Cl. CPC G01R 33/288; G01R 33/30; G01R 33/381; G01R 33/4816

(57) ABSTRACT

A method for localization of an object to be imaged in an examination tube of an MRI system. The method includes: obtaining projection measurement data of an MR projection measurement in at least one direction perpendicular to a longitudinal direction of the examination tube; and determining, as a function of the projection measurement data, at least one distance of the object from an inner wall of the examination tube.

### TECHNICAL FIELD

The present disclosure relates to a method for the localization of an object to be imaged in an examination tube of a magnetic resonance tomography system (MRT system, also MRI system) and to a method, based thereon, for operating an MRI system. The disclosure further relates to a data processing system for implementing such methods, to an MRI system having such a data processing system, and to a corresponding computer program product.

### BACKGROUND

In magnetic resonance imaging (MR imaging), the spins of the object to be imaged are deflected from their rest position with resonant radio frequency (RF) fields. These RF fields cause warming of the object, in particular tissue, which is described by the specific absorption rate (SAR). Especially in the immediate vicinity of a transmit coil, in particular a transmit coil that is installed in the scanner housing of the MRI scanner outside the examination tube (also known as the “bore”) for the object to be imaged, high intensities and corresponding heating may occur locally.

In order to avoid this, an estimated distance of the object from the inner wall of the examination tube is assumed, for example, and the transmit power of the corresponding transmit coil is restricted in accordance with this estimated distance. Because the actual distance is not known or verified, comparatively conservative estimates are taken as the basis here; that is to say, the estimated distance is generally smaller than the minimum actual distance of the object from the inner wall. This has the consequence that the transmit power is possibly limited further than necessary. This in turn leads to reduced image quality.

It would be conceivable in principle to determine the position of the object in the examination tube by means of a camera system and/or other external sensors, instead of taking the estimated distance as the basis. However, this leads to increased hardware complexity.

In the publication by D. Grodzki et al., “Ultrashort Echo Time Imaging Using Pointwise Encoding Time Reduction With Radial Acquisition (PETRA),” the PETRA sequence is described in which the outer k-space is filled with radial half-projections while the k-space center undergoes point-by-point Cartesian sampling. This hybrid sequence combines the features of single-point imaging with radial projection imaging.

The publication M. Robson et al.: “Magnetic resonance: an introduction to ultrashort TE (UTE) imaging,” J. Comput. Assist. Tomogr. 27, 825-46, provides inter alia an overview of the clinical use of UTE pulse sequences for imaging tissue or tissue components.

The publication by A. Y₁d₁z et al., “Zero Echo Time Musculoskeletal MRI: Technique, Optimization, Applications, and Pitfalls,” Radiographics 42, 1398-1414, describes ZTE imaging, an MRI technique that produces images similar to those obtained with radiography or CT. ZTE is used in particular to make tissue, such as bone, with very short T2 values readily visible.

### SUMMARY

It is an object of the present disclosure to specify a possibility for the localization of an object to be imaged in an examination tube of an MRI system without additional sensors being required for this purpose.

This object is achieved by the subject matter of the independent claim. Advantageous developments and preferred aspects form the subject matter of the dependent claims.

The aspect of the disclosure is based on the idea of ascertaining a distance of the object from the inner wall of the examination tube as a function of projection measurement data of a magnetic resonance projection measurement (MR projection measurement) in at least one direction perpendicular to a longitudinal direction of the examination tube.

In accordance with one aspect of the disclosure, a method for the localization of an object to be imaged in an examination tube of the MRI system is specified. Projection measurement data of an MR projection measurement in at least one direction perpendicular to a longitudinal direction of the examination tube is obtained or is generated by means of the MRI system. At least one distance of the object from an inner wall of the examination tube is determined as a function of the projection measurement data.

In various aspects, the disclosed method may be purely computer-implemented. Unless stated otherwise, all the steps of the computer-implemented method may be performed by a data processing system that contains at least one data processing device. In particular, the at least one data processing device is configured or adapted to execute the steps of the computer-implemented method. For this purpose, the at least one data processing device may store, for example, a computer program containing commands which, when they are executed by the at least one data processing device, cause the at least one data processing device to execute the computer-implemented method. The computer-implemented method may also be implemented entirely or partially in hardware. The expressions “data processing system” and “at least one data processing device” may be used interchangeably here and below. This also applies to corresponding expressions derived therefrom.

For the case in which the at least one data processing device contains two or more data processing devices, certain steps implemented by the at least one data processing device may also be understood to mean that different data processing devices implement different steps or different parts of a step. In particular, it is not necessary for each data processing device to implement the steps. In other words, the implementation of the steps may be distributed over the two or more data processing devices.

From each aspect of the computer-implemented method is obtained a corresponding aspect of a method for the localization of an object to be imaged, which method is not purely computer-implemented and is obtained by incorporating appropriate steps for generating the projection measurement data, in other words in particular implementing the MR projection measurement as a component of the method. In such aspects, the MR projection measurement is performed by means of an MRI system that may also contain the data processing system, for example.

An MR projection measurement may be understood to mean an MR measurement that does not use three-dimensional spatial encoding but instead merely one-dimensional or two-dimensional spatial encoding. In the present case, therefore, the MR projection measurement does not use spatial encoding in the longitudinal direction, hereinafter referred to as the Z-direction, but instead merely one-dimensional spatial encoding in a plane that is perpendicular to the Z-direction, which plane is defined by an X-direction, for example a horizontal direction, and a Y-direction, for example a vertical direction, or two-dimensional spatial encoding in the X-Y plane. Here, the Z-direction may correspond in particular to a direction of the main magnetic field, also referred to as B0, of the MRI system. Two-dimensional MR projection measurements, therefore, correspond in effect to a fluoroscopy image with infinitely large slice thickness. MR projection measurements have the advantage for the disclosed method that they may be performed within a very short amount of time, and the MR signals originate from a very large volume so that very little noise is produced.

In the case of MR projection measurements that are perpendicular to the longitudinal direction, the extent of the object in the interior of the examination tube may be determined, and therefore, the corresponding distances of the object from the inner wall of the examination tube. In a one-dimensional MR projection measurement along a direction w=a*x+b*y, wherein x is a vector in the X-direction and y is a vector in the Y-direction, the at least one distance includes a distance of the object from the inner wall in the direction of w on one side of the inner wall and optionally a distance of the object from the inner wall in the direction of w on the opposite side of the inner wall. In a two-dimensional MR projection measurement in the X-Y plane, at least one distance may contain one, two, or more distance(s) of the object from the inner wall in one or more directions in the X-Y plane from the inner wall. Localizing the object corresponds to determining the at least one distance.

The MR projection measurement may be performed, for example, as a PETRA sequence or part of a PETRA sequence or as a UTE sequence or part of a UTE sequence or as a ZTE sequence or part of a ZTE sequence. In particular, other MRI sequences with a short echo time, for example, an echo time of 1 ms or shorter, may also be used.

The one-dimensional MR projection measurement may be performed here in the whole region from one side of the inner wall to the opposite side. Similarly, the two-dimensional MR projection measurement may be performed at every point as far as the inner wall of the examination tube. The at least one distance may then be determined between the inner wall and the position(s) at which the amplitude of the MR signals received from the object disappear or at which the amplitude becomes less than a predetermined threshold value. If this does not occur, the corresponding distance may be equal to zero because the inner wall is in contact with the object.

However, in some aspects, it is also possible that measurements do not or cannot reach quite as far as the inner wall of the examination tube. This may be the case in particular with MRI systems with an examination tube having a tube diameter of 70 cm or more. It may then arise that, in the measured region, the amplitude of the MR signals received from the object do not disappear or do not fall below the threshold value even though the object is not in contact with the inner wall. In this case, the projection measurement data in the intermediate space between the measured region and the inner wall may be extrapolated while taking into account, for example, typical expected dimensions of the object, in particular, body parts such as arms, legs, et cetera. Instead of the typical expected dimensions, in some aspects, the actual dimensions of the object may also be determined in advance.

The projection measurement data may be present in the k-space in particular and may be fully-sampled data in accordance with the Nyquist criterion, for example. In order to determine the at least one distance, the projection measurement data may then be transformed into the image space by means of a Fourier transform. Alternatively, in the case of data that is not fully sampled, known reconstruction methods may be used to transform the projection measurement data into the image space. Alternatively, the projection measurement data may also be present in the image space.

The disclosed method allows the position of the object in the examination tube, in particular its distances from the inner wall, to be determined reliably and automatically without the need to use external sensors for this purpose. Furthermore, it is possible to monitor the position of the object even during an ongoing MRI examination. It is consequently possible to use a greater transmit power of transmit coils installed in the housing of the MRI scanner outside the examination tube without risking excessive local SAR values.

For example, after the at least one distance has been determined, an MR imaging measurement sequence for imaging the object to be imaged or part of such an MR imaging measurement sequence may be performed, wherein during the MR imaging measurement sequence or the part of the MR imaging measurement sequence, a transmit power of at least one transmit coil of the MRI system, which is installed in the MRI system outside the examination tube, is limited to a permissible range that is determined as a function of the at least one distance.

In accordance with at least one aspect, the MR projection measurement includes a PETRA sequence or part of a PETRA sequence, in particular, a two-dimensional PETRA sequence or part of a two-dimensional PETRA sequence.

PETRA sequences have the advantage that it is possible to work with very small flip angles so that the MR projection measurement does not cause perturbations to the MR imaging measurement sequence. In addition, PETRA sequences with their ultrashort echo times are particularly robust with respect to undesirable effects in the vicinity of the inner wall of the examination tube, such as gradient non-linearities, B0 perturbations, and so on. Signal cancellations or distortions, which would be a risk in the case of longer echo times or spin-echo sequences, may be reliably avoided in this way.

In accordance with at least one aspect, the MR projection measurement is a one-dimensional first MR projection measurement in a first direction perpendicular to the longitudinal direction of the examination tube. The projection measurement data is, therefore, referred to as first projection measurement data. At least one first distance of the at least one distance is determined as a function of the first projection measurement data.

As already mentioned above, the first direction may be expressed as w1=a1*x+b1*y. The at least one first distance contains a first distance of the object from the inner wall in the direction of w1 on one side of the inner wall and optionally a further first distance of the object from the inner wall in the direction of w1 on the opposite side of the inner wall. The permissible range for the transmit power may, therefore, be determined as a function of a minimum distance of the object from the inner wall, for example, corresponding to the smallest distance of the at least one distance.

Such aspects have the advantage that a one-dimensional MR projection measurement may be performed in extremely quick time, for example, in less than 10 ms, because only a single line or spoke in the k-space has to be sampled.

The one-dimensional MR projection measurement may, therefore, be performed particularly simply even during dead times of the MR imaging measurement sequence. In particular, the one-dimensional MR projection measurement may be repeated once or multiple times with different directions in order to ascertain more distances between the object and the inner wall and, therefore, to localize the object more precisely as a result. In particular, it is possible that the different one-dimensional MR projection measurements are performed in different dead times of the MR imaging measurement sequence. A dead time or dead time phase may be understood here as a time period within which no RF pulses are being irradiated, no gradients are being switched, and no MR signals are being acquired. In the case of a turbo-spin-echo (TSE) sequence as an MR imaging measurement sequence, the MR projection measurement may be performed every couple of seconds, for example, each time after a repetition time TR has elapsed.

In accordance with at least one aspect, the MR projection measurement consists of at least one MR projection measurement sequence, wherein a maximum echo time of the MR projection measurement sequence is less than or equal to 2 ms or less than or equal to 1 ms.

In accordance with at least one aspect, second projection measurement data of a one-dimensional second MR projection measurement is obtained in a second direction that differs from the first direction and is perpendicular to the longitudinal direction of the examination tube, or said data is generated by means of the MRI system. At least one second distance of the at least one distance is determined as a function of the second projection measurement data.

In such aspects, the one-dimensional MR projection measurement is therefore repeated at least once with a different direction, as mentioned above. The second direction may be expressed as w2=a2*x+b2*y. The at least one second distance contains a second distance of the object from the inner wall in the direction of w2 on one side of the inner wall and optionally a further second distance of the object from the inner wall in the direction of w2 on the opposite side of the inner wall.

The at least one distance, therefore, includes, in particular, the at least one first distance and the at least one second distance and, in some aspects, at least one further distance that is determined by means of one or more further repetitions of the one-dimensional MR projection measurement with further directions. The permissible range for the transmit power may, therefore, be determined as a function of a minimum distance of the object from the inner wall, for example, corresponding to the smallest distance of the at least one distance.

Similarly, in aspects in which the MR projection measurement is a two-dimensional MR projection measurement, the minimum distance may be determined as the smallest distance of the at least one distance and, for example, the permissible range for the transmit power may be determined based on the minimum distance.

In accordance with at least one aspect, reference measurement data of an MR reference measurement is obtained or is generated by means of the MRI system. A position change of the object in the examination tube is detected as a function of a reconciliation of the projection measurement data with the reference measurement data.

In particular, the at least one distance may be determined as a function of a result of the reconciliation, and/or the permissible range for the transmit power may be determined or updated as a function of the result of the reconciliation.

The MR reference measurement is performed, in particular, before the MR projection measurement and before the start of the MR imaging measurement sequence, for example. The MR reference measurement may likewise be a one-dimensional or two-dimensional MR projection measurement or also a three-dimensional MR measurement. The projection measurement data may then be compared with the reference measurement data, wherein the reference measurement data is possibly converted from 3D to 2D or from 3D or 2D to the corresponding 1D direction. Changes in the positioning of the object may be detected quickly in this way.

In accordance with at least one aspect, as a function of the projection measurement data at least one position in the plane that is perpendicular to the longitudinal direction of the examination tube is determined, at which position an MR signal intensity in accordance with the projection measurement data is less than or equal to a predetermined limit value, and the at least one distance is determined based on the at least one position.

In this case, the MR projection measurement is therefore performed in particular right up to the inner wall of the examination tube. The at least one position at which the MR signal intensity in accordance with the projection measurement data is less than or equal to a predetermined limit value may be interpreted as the outer limit of the object in relation to the inner wall. The at least one distance may be determined particularly precisely as a result. In this case, a diameter of the examination tube is, in particular, less than 70 cm, for example, is equal to 60 cm.

In accordance with at least one aspect, the MR projection measurement is performed at least in part during a dead time phase between a first part of the MR imaging measurement sequence and a second part of the MR imaging measurement sequence.

In this way, advantageously, the MR projection measurement may be performed during the actual examination of the object. In particular, a repeated determination or a monitoring of the at least one distance or of the minimum distance may be realized in this way.

In accordance with a further aspect of the disclosure, a method for operating an MRI system is specified. Here, a disclosed method for the localization of an object to be imaged in an examination tube of the MRI system is performed. A permissible range for a transmit power of at least one transmit coil, in particular at least one RF transmit coil, of the MRI system that is installed outside the examination tube in the MRI system, is determined as a function of the at least one distance, in particular by means of the data processing system. At least part of an MR imaging measurement sequence for imaging the object to be imaged is performed, wherein during the performance of the MR imaging measurement sequence or the part of the MR imaging measurement sequence, the transmit power of the at least one transmit coil is limited to the permissible range, in particular by means of a control system of the MRI system.

The at least one transmit coil may be installed in a scanner housing of the MRI scanner of the MRI system which contains the examination tube, for example. In particular, the at least one transmit coil may contain what is known as a body coil. It should be noted here that this does not mean a local coil that is located within the examination tube and affixed directly on the object, and which is sometimes also referred to as a “body coil.”

In particular, the at least one transmit coil is used during the MR imaging measurement sequence or during the part of the MR imaging measurement sequence in order to irradiate one or more radio-frequency (RF) pulses into the object. The transmit power corresponds to the radiated power of the RF pulses. In this way, excessive heating of the object may be avoided through the limitation of the transmit power to the permissible range.

The permissible range may be determined, for example, as a function of at least one predetermined maximum value for the mean amount of amplitude of a B1 field during the MR imaging measurement sequence or for the mean square amplitude of the B1 field during at least one predetermined time period. Each time period of the at least one time period may lie in the range [1 s, 10 min], for example. In particular, one of the at least one maximum values is assigned to each time period of the at least one time period. The permissible range may correspond to a range [0, Pₘₐₓ], for example, wherein Pₘₐₓ corresponds to a maximum transmit power. The maximum transmit power may, therefore, be determined in such a way that the mean amount of amplitude or the square amplitude over each time period of the at least one time period is less than or equal to the correspondingly assigned maximum value.

For example, a first time period of the at least one time period may lie in the range [1 s, 30 s] or in the range [5 s, 15 s] or may be equal to 10 s. For example, a second time period of the at least one time period may lie in the range [3 min, 9 min] or in the range [4 min, 8 m] or may be equal to 6 min.

In accordance with at least one aspect, the MR projection measurement is performed at least in part during a dead time phase between a first part of the MR imaging measurement sequence and a second part of the MR imaging measurement sequence. The transmit power of the at least one transmit coil is limited to the permissible range during the second part of the MR imaging measurement sequence.

In accordance with at least one aspect, the at least one distance of the object from the inner wall contains two or more distances of the object from the inner wall at different positions in a plane that is perpendicular to the longitudinal direction of the examination tube. The permissible range for the transmit power is determined as a function of a minimum distance of the two or more distances.

Here, the two or more distances may be determined from a two-dimensional MR projection measurement or from one or more one-dimensional projection measurements, as explained above.

Further aspects of the disclosed method for operating an MRI system follow directly from the various aspects of the method for the localization of an object to be imaged and vice versa. In particular, individual features and associated explanations and advantages relating to the various aspects concerning the disclosed method for the localization of an object to be imaged may be applied analogously to corresponding aspects of the disclosed method for operating an MRI system and vice versa.

In accordance with a further aspect of the disclosure, a data processing system is specified that is adapted to perform a disclosed method for the localization of an object to be imaged.

In the present disclosure, the terms “data processing system” and “at least one data processing device” may be used interchangeably. A data processing device may be understood to mean, in particular, a data processing device that contains a processing circuit. Thus, the data processing device may process in particular data for performing computing operations. These include, if applicable, also operations for performing indexed accesses to a data structure, for instance, to a look-up table (LUT), and also a data processing process implemented in hardware.

The data processing device may contain in particular one or more computers, one or more microcontrollers, and/or one or more integrated circuits, for example one or more application-specific integrated circuits (ASIC), one or more field-programmable gate arrays (FPGA), and/or one or more systems on a chip (SoC). The data processing device may also contain one or more processors, for example one or more microprocessors, one or more central processing units (CPU), one or more graphics processing units (GPU), and/or one or more signal processors, in particular one or more digital signal processors (DSP). The data processing device may also contain a physical or virtual interconnection of computers or other of the aforementioned units.

In various exemplary aspects, the data processing device contains one or more hardware and/or software interfaces and/or one or more memory units.

A memory unit may be embodied as a volatile data storage medium, for example as a dynamic random access memory (DRAM) or a static random access memory (SRAM), or as a non-volatile data storage medium, for example as a read-only memory (ROM), as a programmable read-only memory (PROM), as an erasable programmable read-only memory (EPROM), as an electrically erasable programmable read-only memory (EEPROM), as a flash memory or flash EEPROM, as a ferroelectric random access memory (FRAM), as a magnetoresistive random access memory (MRAM), or as a phase-change random access memory (PCRAM).

In accordance with a further aspect of the disclosure, an MRI system for performing an MR imaging measurement sequence for imaging an object to be imaged is specified. The MRI system has an MRI scanner with an examination tube and a disclosed data processing system.

In particular, the MRI system has all further components necessary to perform a known MR imaging measurement sequence, such as a main magnet unit, one or more RF transmit coils, one or more receive coils, one or more gradient coils, a control system for actuating the MRI scanner, and so on.

In accordance with at least one aspect, the MRI system has a control system for actuating the MRI scanner. The MRI scanner has at least one transmit coil installed outside the examination tube, in particular in the scanner housing of the MRI scanner. The data processing system is adapted to determine a permissible range for a transmit power of the at least one transmit coil as a function of the at least one distance. The control system is configured to actuate the MRI scanner in order to perform the MR imaging measurement sequence so that the transmit power of the at least one transmit coil is limited to the permissible range.

In particular, the control system may contain one or more data processing devices in accordance with the definition above.

Further aspects of the disclosed MRI system follow directly from the various aspects of the disclosed method and vice versa. In particular, individual features and associated explanations and advantages relating to the various aspects concerning the disclosed method may be applied analogously to corresponding aspects of the disclosed MRI system. In particular, the disclosed MRI system is designed or programmed to perform a disclosed method for operating an MRI system. In particular, the disclosed MRI system performs the disclosed method for operating an MRI system.

In accordance with a further aspect of the disclosure, a computer program containing commands is specified. When the commands are executed by a data processing system, the commands cause the data processing system to perform a disclosed method for the localization of an object to be imaged.

For example, the commands may exist as program code. The program code may be provided, for example, as binary code or assembler and/or as source code of a programming language, for instance, C, and/or as program script, for instance, Python.

In accordance with a further aspect of the disclosure, a further computer program containing commands is specified. When the further commands are executed by a disclosed MRI system, for example, by means of the data processing system and/or the control system of the MRI system, the commands cause the MRI system to perform a disclosed method for operating an MRI system.

For example, the further commands may exist as program code. The program code may be provided, for example, as binary code or assembler and/or as source code of a programming language, for instance, C, and/or as program script, for instance, Python.

In accordance with a further aspect of the disclosure, a computer-readable storage medium is specified, which stores a disclosed computer program and/or a disclosed further computer program.

The computer program, the further computer program, and the computer-readable storage medium are each computer program products containing the commands or the further commands.

Further features and combinations of features of the aspects of the disclosure appear in the figures and the description of the figures and in the claims. In particular, further aspects of the disclosure need not necessarily contain all the features of one of the claims. Further aspects of the disclosure may have features and combinations of features that are not mentioned in the claims.

### DESCRIPTION OF THE DRAWINGS

The aspects of the disclosure will be explained in more detail below with reference to specific exemplary aspects and associated schematic drawings. In the figures, identical or functionally equivalent elements may be denoted by the same reference characters. The description of identical or functionally equivalent elements is not necessarily repeated when referring to different figures.

In the figures:

FIG. 1 shows a schematic representation of an exemplary aspect of a disclosed MRI system;

FIG. 2 shows a schematic flow diagram of an exemplary aspect of a disclosed method for operating an MRI system;

FIG. 3 shows a schematic representation of a one-dimensional MR projection measurement to be used in an exemplary aspect of a disclosed method for localizing an object;

FIG. 4 shows a schematic representation of a one-dimensional MR projection measurement to be used in a further exemplary aspect of a disclosed method for localizing an object; and

FIG. 5 shows a schematic representation of an MR imaging measurement sequence to be used in a further exemplary aspect of a disclosed method for operating an MRI system.

### DETAILED DESCRIPTION

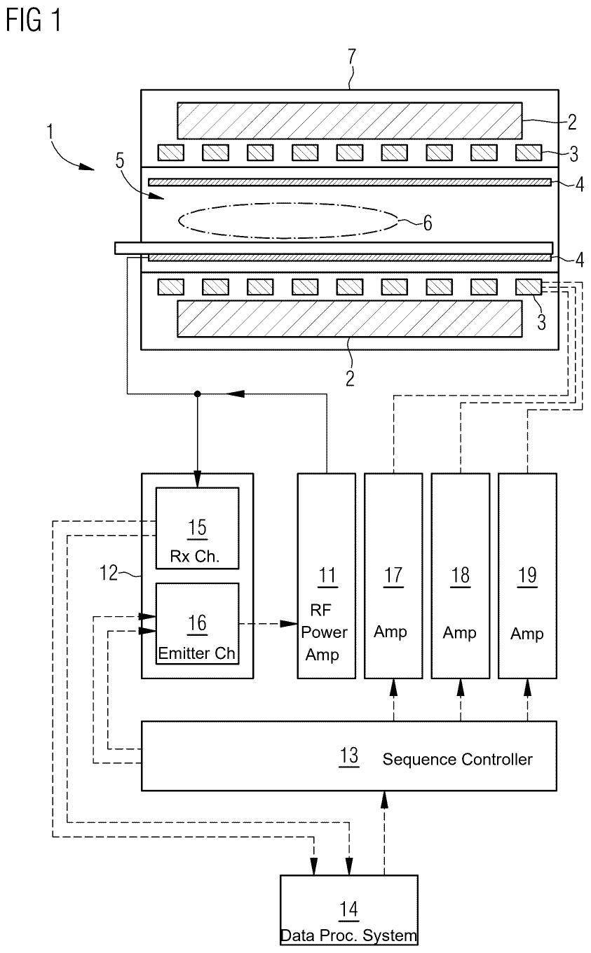

FIG. 1 schematically shows an exemplary aspect of an MRI system 1 in accordance with the aspects of the disclosure. The MRI system 1 comprises an MRI scanner with a scanner housing 7 that defines an examination tube 5 and a main magnet arrangement 2 that is configured such that a main magnetic field, also referred to as a polarizing magnetic field or B0, is generated within the examination tube 5. The MRI system 1 comprises an RF system 4, 11, 12 that is configured to irradiate RF pulses in the direction of an object 6 arranged in the examination tube 5, in particular a body part of a patient, and to receive the MR signals emitted by the object 6. For example, the main magnet arrangement 2 may generate a homogeneous main magnetic field and at least one RF coil 4 of the RF system 4, 11, 12 may emit an RF field B1. The MRI system 1 also has a sequence controller 13.

In accordance with known MRI techniques, the object 6 is exposed to the main magnetic field so that the nuclear spins in the object are set in precession at their characteristic Larmor frequency around the direction of the main magnetic field. A net magnetic moment Mz is generated in the direction Z of the main magnetic field, and the randomly oriented magnetic moments of the nuclear spins cancel each other out in the x-y plane.

When the object 6 is then exposed to the RF field, lying, for example, in the X-Y plane and close to the Larmor frequency, the net magnetic moment rotates out of the Z-direction and generates a net magnetic moment with a projection that rotates in the X-Y plane at the Larmor frequency. In response to this, MR signals are emitted by the excited spins when they return to their state before the excitation. The emitted MR signals are, for example, ascertained by the at least one RF coil 4 and/or one or more special receive coils, digitized in a receive channel 15 of an RF controller 12 of the RF system 4, 11, 12, and processed by the at least one processor in order to reconstruct an MR image, for example by means of a known reconstruction technique.

In particular, the gradient coils 3 of the MRI system 1 may generate magnetic field gradients Gx, Gy, and Gz for spatial encoding of the MR signals. Accordingly, MR signals are emitted only by those nuclei of the object 6 that correspond to the respective Larmor frequency. For example, Gz is used together with an RF pulse in order to select a slice that is perpendicular to the Z-direction and may, therefore, also be referred to as a slice selection gradient. In an alternative example, Gx, Gy, and Gz may be used in any given predefined combination with an RF pulse in order to select a slice that is perpendicular to the vector sum of the gradient combination. The gradient coils 3 may be supplied with current by the respective amplifiers 17, 18, 19 in order to generate the respective gradient fields in the X-direction, Y-direction, or Z-direction. Each amplifier 17, 18, 19 may contain a corresponding digital/analog converter that is controlled by the sequence controller 13 in order to generate corresponding gradient pulses at predefined points in time.

The sequence controller 13 may control the generation of RF pulses through an emitter channel 16 of the RF controller 12 and an RF power amplifier 11 of the RF system 4, 11, 12.

It should be noted that the components of the MRI system 1 may also be arranged differently than in FIG. 1. For example, the gradient coils 3 may be arranged within the examination tube 5 in a similar manner as for the at least one RF coil 4. It should be noted, furthermore, that each component of the MRI system 1 may contain further elements necessary for its operation and/or additional elements that provide functions other than those described in the present disclosure.

The MRI system 1 comprises a data processing system 14 configured to perform a disclosed method for localizing the object 6 in the examination tube 5. As a result of this method, the data processing system 14 determines at least one distance of the object 6 from an inner wall 20 of the examination tube 5, in particular, at least one distance in the X-Y plane.

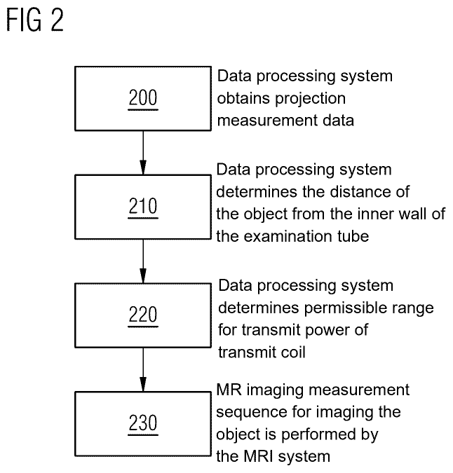

The MRI system 1 may also perform a disclosed method for operating an MRI system. FIG. 2 schematically shows a flow diagram of such a method with steps 200 to 230, wherein steps 200 and 210 represent a disclosed method for localizing the object 6 in the examination tube 5.

In step 200, the data processing system 14 obtains projection measurement data 23 of an MR projection measurement in at least one direction perpendicular to a longitudinal direction of the examination tube 5, or the projection measurement data 23 is generated by the MR projection measurement being performed by the MRI system 1. In step 210, the data processing system 14 determines, as a function of the projection measurement data 23, at least one distance of the object 6 from an inner wall 20 of the examination tube 5.

In step 220, the data processing system 14 determines a permissible range for a transmit power of at least one transmit coil, for example, the RF coil 4, of the MRI system 1 that is installed outside the examination tube 5, as a function of the at least one distance. To this end, the data processing system 14 determines in particular a maximum transmit power Pₘₐₓ for the at least one transmit coil so that the mean square RF field strength |B1|² averaged over a predetermined time period, for example 10 s or 6 min, does not exceed a predetermined maximum value when the at least one transmit coil is operated at the maximum transmit power Pₘₐₓ. A corresponding maximum value may also be predetermined for multiple predetermined time periods, for example. The maximum transmit power Pₘₐₓ may then be determined in particular such that for none of the time periods does the mean square RF field strength |B1|² exceed the respective maximum value.

In step 230, at least part of an MR imaging measurement sequence 25 for imaging the object 6 is performed by means of the MRI system 1, wherein the transmit power of at least one transmit coil is limited to the permissible range.

Steps 200 to 230 may also be performed multiple times, wherein in each case, the MR projection measurement is performed between successive parts of the MR imaging measurement sequence 25 in order in this way to monitor continuously the position of the object 6 and correspondingly to adapt the permissible range continuously or repeatedly.

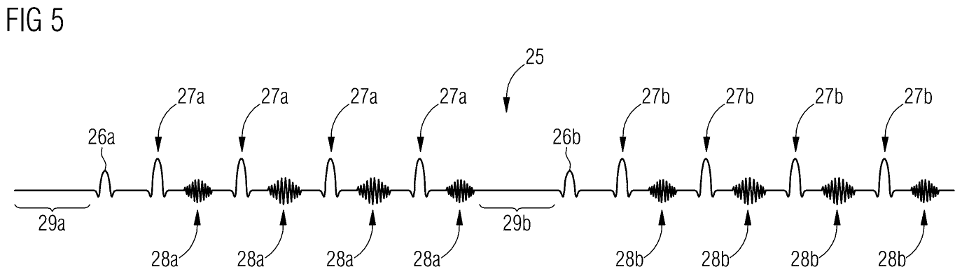

With regard to this aspect, FIG. 5 shows a schematic representation of an MR imaging measurement sequence 25. By way of example, a TSE sequence is shown. A 90° pulse 26a is followed by a series of 180° pulses 27a, and after each 180° pulse 27a, a spin-echo signal 28a is measured. This is followed by a further 90° pulse 26b followed by a further series of 180° pulses 27b, wherein and after each 180° pulse 27b in turn a spin-echo signal 28b is measured. MR projection measurements may then be performed, for example, in a dead time phase 29a before the 90° pulse 26a and/or in a dead time phase 29b between the last spin echo 28a and the further 90° pulse 26b.

In some aspects, a PETRA sequence may be used for the MR projection measurement. This has the advantage that it is possible to work with very small flip angles, and so the actual measurement for imaging the object 6 does not cause perturbations. In addition, with its ultrashort echo times, it is particularly robust with respect to undesirable effects in the vicinity of the inner wall 20, such as gradient non-linearities, B0 perturbations, and so on.

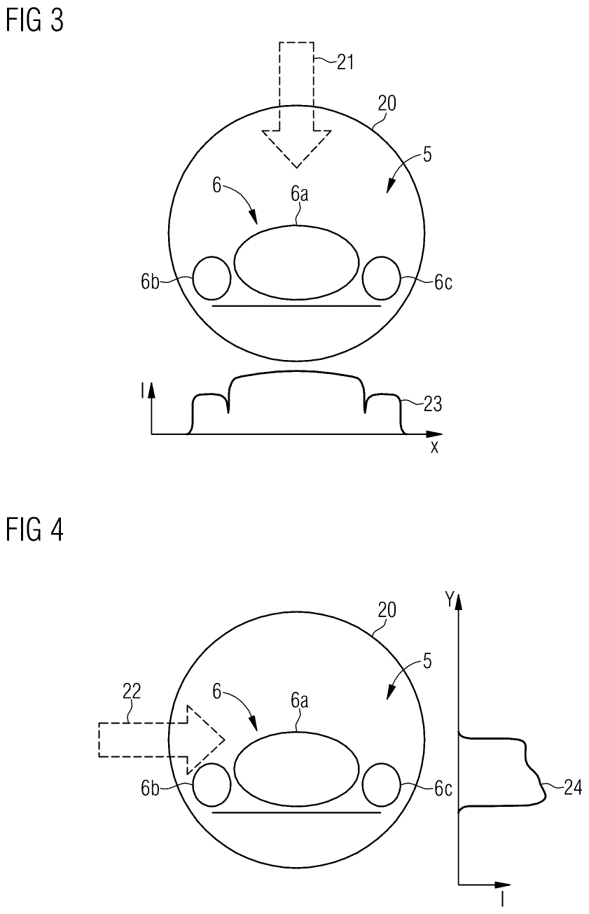

Both two-dimensional MR projection measurements and also one-dimensional MR projection measurements may be used. In particular, a combination of multiple one-dimensional MR projection measurements, each with different directions in the X-Y plane, may also be used. In the case of one-dimensional MR projection measurements, only one line through the object 6 is recorded, as shown schematically in FIG. 3 and FIG. 4 for two different projection directions 21, 22.

Accordingly, FIG. 3 shows an outline of the scenario that the one-dimensional MR projection measurement is performed along the X-direction. The resulting signal intensity in the image space I is shown as the curve 23. It is apparent that the curve 23 is at its highest in the region of the patient's trunk 6a, is slightly lower in the region of the arms 6b, 6c, and then in each case drops to zero toward the inner wall 20. The position of the inner wall 20 is known in the coordinate system of the spatial encoding. Accordingly, the respective distance of the object 6 from the inner wall 20 may be inferred directly from the position at which the curve 23 reaches zero.

FIG. 4 shows an outline of the scenario that the one-dimensional MR projection measurement is performed along the X-direction. The resulting signal intensity in the image space I is shown as the curve 24. It is apparent that the curve 24 is at its highest close to the patient couch 4 and then in each case drops to zero toward the inner wall 20. Accordingly, the respective distance of the object 6 from the inner wall 20 may be inferred directly from the position at which the curve 24 reaches zero.

One-dimensional MR projection measurements have the advantage that they may be performed in a very short time because only one line or spoke through the k-space has to be sampled. In a PETRA sequence, at least three repetitions are measured for one complete spoke, for example, namely, two repetitions in opposite radial directions out from the k-space center, as well as at least one for the k-space center, wherein the latter may possibly be reused from previous measurements. Alternatively, in a PETRA sequence, just one radial measurement may also be performed for the measurement of one spoke, and, as is known from the partial Fourier transform method, the other half of the spoke may be covered by means of zero filling. Since one repetition only takes 2-3 ms, for example, a one-dimensional MR projection measurement may be measured in significantly less than 10 ms. Consequently, it may become particularly advantageous in dead time phases 29a, 29b of the actual ongoing MR imaging measurement sequence 25, for example, every couple of seconds during a TSE acquisition at the end of a TR time period.

In some aspects, the one-dimensional projection direction may be changed for each pass so as to project from various directions.

In some aspects it is provided to perform a complete two-dimensional or also three-dimensional reference measurement at the start of the examination. The projection measurement data acquired later may then be compared with the results from the reference measurement, wherein in particular the reference measurement is converted into the corresponding directions of the projection measurement data. Changes in the positioning of the object 6 may be detected quickly in this way.

In various aspects of the method is proposed with which, using one-dimensional or two-dimensional MR projection measurements, information about the positioning of an object during an ongoing MR imaging measurement sequence 25 may be ascertained. Advantages of the method include that monitoring of the positioning and especially the minimum distance of the object 6 from the inner wall 20 is also possible during an ongoing examination and especially without further external sensors.

Independent of the grammatical term usage, individuals with male, female or other gender identities are included within the term.

1. A method for localization of an object to be imaged in an examination tube of a magnetic resonance imaging (MRI) system, the method comprising:
obtaining projection measurement data of an MR projection measurement in at least one direction perpendicular to a longitudinal direction of the examination tube; and
determining, as a function of the projection measurement data, at least one distance of the object from an inner wall of the examination tube.

2. The method as claimed in claim 1, wherein the MR projection measurement:
is a two-dimensional MR projection measurement; and/or
includes an Encoding Time Reduction with Radial Acquisition (PETRA) sequence or part of a PETRA sequence; and/or
includes an Ultrashort Echo Time (UTE) sequence or part of a UTE sequence; and/or
includes a Zero Echo Time (ZTE) sequence or part of a ZTE sequence.

3. The method as claimed in claim 1, wherein the MR projection measurement is a one-dimensional first MR projection measurement in a first direction perpendicular to the longitudinal direction of the examination tube, the projection measurement data is first projection measurement data, and at least one first distance of the at least one distance is determined as a function of the first projection measurement data.

4. The method as claimed in claim 3, further comprising:
obtaining second projection measurement data of a one-dimensional second MR projection measurement in a second direction perpendicular to the longitudinal direction of the examination tube; and
determining at least one second distance of the at least one distance as a function of the second projection measurement data.

5. The method as claimed in claim 1, further comprising:
obtaining reference measurement data of an MR reference measurement; and
detecting a position change of the object in the examination tube as a function of a reconciliation of the projection measurement data with the reference measurement data.

6. The method as claimed in claim 1, wherein the MR projection measurement consists of at least one MR projection measurement, and a maximum echo time of the MR projection measurement is less than or equal to 2 ms.

7. The method as claimed in claim 1, further comprising:
determining, as a function of the projection measurement data, at least one position in a plane that is perpendicular to the longitudinal direction of the examination tube, at which position an MR signal intensity in accordance with the projection measurement data is less than or equal to a predetermined limit value; and
determining the at least one distance based on the at least one position.

8. A method for operating a magnetic resonance imaging (MRI) system, comprising:
performing the method for localization of an object to be imaged in an examination tube of the MRI system as claimed in claim 1;
determining a permissible range for a transmit power of at least one transmit coil of the MRI system that is installed outside the examination tube as a function of the at least one distance; and
performing at least part of an MR imaging measurement sequence for imaging the object to be imaged, wherein the transmit power of at least one transmit coil is limited to the permissible range.

9. The method as claimed in claim 8, further comprising:
performing the MR projection measurement at least in part during a dead time phase between a first part of the MR imaging measurement sequence and a second part of the MR imaging measurement sequence,
wherein the transmit power of the at least one transmit coil is limited to the permissible range during the second part of the MR imaging measurement sequence.

10. The method as claimed in claim 8, wherein the at least one distance of the object from the inner wall contains two or more distances of the object from the inner wall at different positions in a plane that is perpendicular to the longitudinal direction of the examination tube and the permissible range for the transmit power is determined as a function of a minimum distance of the two or more distances.

11. The method as claimed in claim 8, further comprising:
determining the permissible range as a function of a predetermined maximum value for a mean amount of amplitude of a B1 field or for a mean square amplitude of the B1 field during a predetermined time period.

12. A data processing system that is adapted to perform the method as claimed in claim 1.

13. A magnetic resonance imaging (MRI) system for performing an MR imaging measurement sequence for imaging an object to be imaged, the MRI system comprising:
an MRI scanner with an examination tube; and
a data processing system as claimed in claim 12.

14. The MRI system as claimed in claim 13, further comprising:
a control system configured to actuate the MRI scanner,
wherein:
the MRI scanner has at least one transmit coil that is installed outside the examination tube;
the data processing system is adapted to determine a permissible range for a transmit power of the at least one transmit coil as a function of the at least one distance; and
the control system is configured to actuate the MRI scanner in order to perform the MR imaging measurement sequence so that the transmit power of the at least one transmit coil is limited to the permissible range.

15. A non-transitory computer program product comprising commands which, when executed by a data processing system, cause the data processing system to perform a method as claimed in claim 1.
